(19) United States
(12) Patent Application Publication
(10) Pub. No.: US 2021/0040603 A1
(43) Pub. Date: Feb. 11, 2021

(54) IMPLANTATION OF IONS GENERATED BY LASER ABLATION

(71) Applicant: UNIVERSITY OF LEEDS, Leeds, Yorkshire (GB)

(72) Inventors: Jayakrishnan CHANDRAPPAN, Leeds (GB); Gin JOSE, Leeds (GB); Matthew MURRAY, LEEDS (GB)

(21) Appl. No.: 15/752,131

(22) PCT Filed: Aug. 12, 2016
(86) PCT No.: PCT/GB2016/052512

§ 371 Date: May 18, 2018

(30) Foreign Application Priority Data
Aug. 13, 2015 (GB) 1514431.4

(51) Int. Cl. C23C 14/48; C23C 14/28; G02B 6/122; C03C 23/00

(52) U.S. Cl. CPC C23C 14/48; C23C 14/28; G02B 2006/12188; C03C 23/0055; G02B 6/1225

(57) ABSTRACT

A process for fabricating a substrate comprising a laser-induced plasma assisted modified layer, and a substrate comprising an ion-implanted layer. The process comprises ablating ions from a first target and a separate second target with incident radiation from a laser in the presence of a substrate whereby a quantity of ablated ions from the first target and the second target are separately implanted into the substrate. Ablated ions from the second target are implanted into the substrate amongst implanted ions from the first target. Ablated ions of the first target (e,g Erbium) are a different material compared to ablated ions of the second target (e.g. Ytterbium). The resulting ion-implanted layer may have a substantially uniform distribution of the implanted ions from both the first and second targets collectively, and may be at a significantly greater depth than previously possible, desirably to a well-defined and sharp boundary within the substrate.

### FIELD OF THE INVENTION

The present invention relates to methods for producing a material or substrate comprising a layer of implanted ions, for example cations. The layer of implanted ions may have a uniform distribution of the implanted ions, preferably extending substantially from the surface of the substrate. This distribution of implanted ions may extend to a significantly greater depth than previously possible. The invention further relates to such a material or substrate. The material or substrate may be an optical material or substrate etc. The material or substrate may be a polymer, a glass or a silicon-based material or substrate such as silicon, a silicon compound or a silicate glass, or phosphate glass. The invention also relates to the use of such material or substrate as an optical waveguide and/or an optical amplifier and/or the use of such material or substrate in photonic devices, optical devices and/or measurement devices. The present invention may relate to the doping of a substrate with ions by implanting the dopant ions. The invention may relate to implanting dopant ions using a plasma generated by laser ablation of target dopant material. The laser ablation may be done using an ultrafast laser. Thus, the invention may optionally relate to implanted ions which may be considered to be ultrafast laser plasma assisted dopant ions.

### BACKGROUND

Ion-implantation may currently be achieved e.g. by directing a beam of energetic ions towards the surface of a substrate material for the purposes of implanting ions of the ion beam inside the body of the substrate. The purpose of this is to alter the optical and/or structural properties of the substrate material using the ions so implanted. However, because these ions are kinetically implanted into a target substrate, they penetrate significantly below its surface. The result is a density profile of the implanted ions (as a function of depth into the substrate) which shows a strong and distinct peak below the substrate surface, with a drop in ion density either side. This distribution of implanted ions is very far from uniform, is localised significantly below the surface of the target substrate, and is typically relatively low in implanted ion density. This limits the application of ion-implanted materials (e.g. glasses) produced in this way. Furthermore, the high kinetic energies required of an ion beam to kinetically implant the ions cause significant damage to the material of the substrate, such as cracks, and can change its refractive index. This damage has undesirable consequences as it affects the strength and optical properties of the ion-implanted target substrate.

Femtosecond pulsed laser plasma deposition (fs-PLD) is a different technique compared to ion implantation. This deposition method typically involves ablating a target material with radiation from a laser to produce a hot plume. A quantity of the target material from the plume is then condensed onto a substrate in the form of an overlaid deposit residing at the uppermost surface of the substrate.

The deposited over-layer does not generally alter the structure or properties of the underlying substrate, and thus the substrate serves merely as a support surface upon which to build the laser-ablated over-layer. Careful control of the ablation process parameters can result in some effective control over the structural and optical properties of the deposited over-layer as desired, but not over the structural and optical properties of the underlying substrate material.

The present invention relates to a new and improved process using laser plasma-assisted process for making novel materials comprising implanted ions.

### BRIEF DESCRIPTION

The applicants have found a process which enables ions to be implanted into a substrate to form within the substrate material itself a layer of implanted ions which reside amongst/within the material of the substrate. The substrate may be, for example, a glass. The applicants have found that the layer of implanted ions may extend into the substrate, e.g. from its surface, to a much greater depth than previously possible. The present invention relates to a laser-induced plasma assisted process which is distinct from fs-PLD in that the result is not the deposition of an over-laid film of ablated material onto the top of a substrate surface, but rather, it is the implantation of ions of the plasma into the matrix of the substrate itself.

Implanting ions, such as Rare Earth ions or other ions, offers new applications in photonic device engineering: examples include site-selective doping by masking, direct printing of photonic circuits, fine pattern printing such as a ‘logo’ , integrated optical amplifiers in novel materials, multiple sensors with integrated pump source and data readouts, possibility of single chip multi-sensor design, super-lattice structures by multi-target deposition etc.

In a first of its aspects, the invention may provide a process for fabricating a substrate comprising an ion-implanted layer, the process comprising: ablating ions from a first target with incident radiation from a laser in the presence of a substrate whereby a quantity of ablated ions from the first target is implanted into the substrate; ablating ions from a second target with incident radiation from a laser in the presence of said substrate whereby a quantity of ablated ions from the second target is implanted into the substrate and amongst said implanted ions from the first target; wherein ablated ions of the first target are a different material not comprised amongst ablated ions of the second target. In this way, the substrate is modified to comprise a layer of implanted ions. The substrate may be considered to have been doped by the implantation of such ions.

It will be understood that this process is applicable to multiple targets, and is not limited to the use of only two targets. For example, any number of targets equal to or greater than two in number may be employed in a sequence in which any preceding target is a “first” target, and any succeeding target is a “second” target. Thus, any pair of targets, from amongst a multiplicity of ablation targets, may be considered to comprise a “first” target, and a succeeding “second” target.

As an illustrative example, if three or more separate targets A, B, C . . . etc., are ablated sequentially in that order, then A and B are a first pairing of “first” and “second” targets, and targets “B” and “C” are a second pairing of “first” and “second” targets, and targets “A” and “C” are a third pairing of “first” and “second” targets, and so on.

The inventors have been very surprised to find that even when two different target materials are separately ablated, so that ions from different targets reach the substrate one after the other, the implanted ions reaching the substrate from the second target are still implanted amongst the implanted ions of the first target to the same depth. One might expect that a spatial layering of implanted ions would be produced in these circumstances (e.g. a first ion-implanted layer of ions of the first target, next to a second ion-implanted layer of ions from the second target, without intermixing, or at the very least with incomplete inter-mixing). However, this has been found not to occur.

Without being bound by theory, the inventors postulate that the following scenario takes place. When a given target (e.g. the first) is irradiated by a laser, for example by a pulsed laser, this generates by laser ablation an initial ion cloud of first material for implantation into the surface of the substrate. The initial ablation pulse causes an initial flux of ions to reach the substrate surface whereupon the ions are implanted substantially at the surface, rather than at significant depth. A subsequent laser ablation pulse (by a subsequent laser pulse) at the first target then generates a subsequent flux of ions at the substrate surface, which displace the pre-implanted ions (the initial ion flux) further into the substrate and in doing so substantially occupy the substrate surface region previously occupied by the initial flux of ions. The process of inward displacement of all previously implanted ions in the substrate, by each successive influx of ions at the substrate surface (caused by successive laser pulses at the first target), is thought to “stack-up” implanted ions of the first target material ever further into the body of the substrate in a distribution extending (to below) its surface.

On this basis, it was expected that when a different target (e.g. the second) is irradiated by the pulsed laser, this again would generate by laser ablation a subsequent ion cloud of second material for implantation into the surface of the substrate. As before, it was expected that this subsequent flux of ions from the second target would displace the pre-implanted ions (i.e. from the first target) further into the substrate and in doing so substantially occupy the substrate surface region previously occupied by the ions of the first target. The process of inward displacement of all previously implanted ions (of the first target) in the substrate, by each successive influx of ions from the second target at the substrate surface, was expected to “stack-up” a new and separate layer of implanted ions of the second target material distinct from the existing ion-implanted layer from the first target.

This layering, or stratification, of different ions/target materials has been found not to occur, against all expectation.

For the purposes of a better understanding, and without being bound by theory, is noted that the phenomenology of multi-component diffusion offers a means for interpretation of ion exchange processes expected to occur.

Diffusion, such as in a glass, due to a concentration gradient of one species of ion within the glass typically involves a counter-diffusion of a second species of ion within the glass in order to maintain charge neutrality. Using Fick's first law of diffusion, a diffusion flux of a concentration cᵢ of ion species i amongst a concentration cⱼ of one or more other ion species j may be written as:

$$\frac{d {c}_{i}}{d t} = \frac{d}{d x} [ {D}_{ij} \frac{d {c}_{j}}{d x} ] ; ( sum over j ; i not equal to j )$$

Here, Dᵢⱼ is the inter-diffusion coefficient of ion species i in the gradient of ion species j. This has been considered in detail for the case of diffusion of separate layers/concentrations of different ions within a glass, across the interface between them:

See A. K. Varshneya: “Fundamentals of Inorganic Glasses”: 2^{nd} Edition, Society of Glass Technology 2013; ISBN 9780900682650; pp402-404.

Varshneya predicts that a partially stratified spatial concentration pattern persists at either side (beyond) the interface, and also includes a complex spatial concentration pattern caused by the so-called “uphill diffusion” process across the boundary itself. The prediction is supported well with experimental data.

That prediction and result however, even merely qualitatively speaking, is very far from the spatial distribution of ion concentrations and intermixing of different implanted ion species observed by the inventors according to the invention.

On the contrary, the inventors observe a strong and substantially uniform mixing of implanted ions from the second target in and amongst the implanted ions from the first target with no effective trace of spatially separate and ion concentrations, layers or strata. Indeed, the degree of mixing between ion species may be substantially uniform throughout the ion-implanted layer. Furthermore, a significantly greater ion penetration depth and/or implanted ion density has been found possible, and enhanced optical and structural properties that accompany that. These new and beneficial findings are discussed in detail below.

It is preferable that ion clouds of ablated material from the first and second targets arrive at the substrate at different respective times, e.g. in sequence. This can be achieved by ablating the targets at different respective times, such as sequentially, such that respective ion plumes are generated at different respective times e.g., sequentially, and are controlled so as to arrive at the substrate at different respective times, e.g. sequentially. Alternatively, the two targets may be ablated substantially simultaneously, or otherwise independently, and the targets and substrate configured such that the two resulting ion plumes arrive at the substrate at different respective times, e.g. sequentially. For example, the ablating of material from said second target may be performed after said ablating of material from said first target (e.g. sequentially).

Alternatively, the ablating of material from said second target may be performed substantially simultaneously with said ablating of material from said first target.

The method may then include, for example, sequentially obstructing firstly said quantity of ions from said first target and subsequently said quantity of ions from said second target so that e.g. sequentially said quantity of ions from said first target reaches the substrate before said subsequent quantity of ions from said second target. An obstruction may be periodically or intermittently placed between the path (or intended path) of an ion plume from an ablated target (e.g. a mask, cover, shield, sheet, door, shutter, chopper wheel or the like) to intercept an ion plume, or the substrate itself may be moved intermittently or periodically to as to be positioned behind such an obstruction (e.g. a static obstruction). When the obstruction is removed (e.g. temporarily) then the ion plume from the given target may be free to progress to the substrate, else it is prevented from doing so. In this way, control of the sequence of arrival of ion plumes from the two different targets is able to be achieved and controlled.

The method may, for example, include positioning the substrate closer to said first target than the said second target so that sequentially said quantity of ions from said first target reaches the substrate before said subsequent quantity of ions from said second target. The ablating material from said first and second targets may be repeated sequentially a plurality of times. For example, an extended sequence of alternating ablation as between the two targets (e.g. first target, then second, then first target again, then second target once more . . . and so on). The process may be continues for as long as desired in order to achieve the desired ion-implanted layer properties.

The first target may be ablated for a period of time relatively longer than the period of time for which said second target is ablated thereby to implant into the substrate a greater proportion of ablated ions of the first target relative to ablated ions of the second target. This may be used to control the relative concentrations within the substrate of different ion species from the different target materials.

The first target may be ablated for a period of time substantially the same as the period of time during which said second target is ablated and said first target may contain a greater concentration of said first ions compared to the concentration of said second ions in said second target, thereby to implant into the substrate a greater proportion of ablated ions of the first target relative to ablated ions of the second target. Thus, by appropriate control of the composition of the target materials, one may control the substrate composition, or relative concentrations within the substrate of different ion species from the different target materials.

The first target may be ablated for a period of time substantially the same as the period of time for which said second target is ablated and said first target may be positioned in closer proximity to the substrate than is said second target, thereby to implant into the substrate a greater proportion of ablated ions of the first target relative to ablated ions of the second target. Accordingly, by controlling the spatial geometry (e.g. separation, or spacing) between any one target material and the substrate as compares to the corresponding separation between the other target material and the substrate, one may control the substrate composition, or relative concentrations within the substrate of different ion species from the different target materials.

It is to be understood that any combination of any two or more of the above three techniques for controlling the substrate composition, or relative concentrations within the substrate of different ion species from the different target materials, may be employed together (e.g. ablation time period, target composition variation, target-to-substrate separation).

The substrate may be heated to improve activation energy to facilitate the implantation of ions into the substrate. The optimum temperature to facilitate the implantation of ions will depend on the substrate material used. Preferably, the substrate is heated during the process. The substrate is preferably heated to a temperature less than the glass softening point/temperature (T_{SP} for brevity) of the material of the substrate, or may be heated to a temperature less than, or not exceeding, the temperature of crystallization (T, for brevity) of the material of the substrate, or may preferably be heated to a temperature of about half the glass softening point/temperature (e.g. within the range of temperatures from about 0.4Tₛₚ to about 0.6Tₛₚ, or from about 0.45Tₛₚ to about 0.55Tₛₚ), or less than about half the glass softening point/temperature of the material of the substrate. For example, if Tₛₚ=1400° C., then the substrate may be heated to a temperature within the range of temperatures from about 630° C. to 770° C. (i.e. about 0.45Tₛₚ to about 0.55Tₛₚ).

It is postulated, though not asserted, that the optimal temperature ranges for heating of the substrate are sufficient to promote ion mobility of implanted ions within the matrix of the substrate without damaging the fundamental morphology of that matrix. It is postulated that the appropriate level of heating provides implanting ions with sufficient activation energy to significantly diffuse through the substrate matrix (e.g. potential energy barrier to diffusion) but not so much energy as to inhibit the closer-packing of implanted ions within the matrix.

The substrate may be, or comprise, silicon. The substrate, if silicon, may be heated to a temperature between about 400° C. and about 1000° C., or between about 500° C. and about 800° C., or between about 500° C. and about 700° C., such as about 600° C. or about 650° C.

The substrate may be a glass selected from silica, silicate, phosphate, tellurite, tellurite derivatives, germanate, bismuthate, phosphate glass, and solgel route glasses, or an optical polymer.

The substrates could be a combination of these materials, for example silica on silicon and silicon on insulator (S01), or silicon nitride on silicon (or compounds of silicon).

The optical polymer may be selected from Poly(methyl methacrylate), polyvinyl alcohol, polyether ether ketone, polyethylene terephthalate, polyimide, polypropylene, polydimethylsiloxane (PDMS) and polytetrafluoroethylene.

The substrate may comprise a silicate glass and may be heated to a temperature between about 350° C. and about 1000° C., or between about 450° C. and about 900° C., or between about 500° C. and about 800° C.

The substrate may comprise a silica glass (e.g. soda-lime-silica) and may be heated to a temperature between about 500° C. and about 800° C., between about 500° C. and about 750° C., or between about 500° C. and about 650° C., or between about 600° C. and about 750° C.

The substrate may comprise a tellurite or germanate glass and may be heated to a temperature between about 200° C. and about 400° C. The substrate may comprise a bismuthate glass and may be heated to a temperature between about 200° C. and about 400° C. The substrate may comprise a solgel glass and may be heated to a temperature between about 400° C. and about 600° C.

The substrate may comprise a phosphate glass and may be heated to a temperature between about 200° C. and about 500° C.

The substrate may comprise an optical polymer and may be heated to a temperature between about 50° C. and about 200° C.

The glass softening point/temperature of a material varies according to its composition. In the case of silicates, the glass softening point/temperature decreases with the molar fraction of network modifier. Here the building blocks of the glass network are polyhedra formed around what is known as a network-forming cation, that is, a positively charged ion such as silicon (Si⁴⁺). The four positive charges of the silicon ion lead it to form bonds with four oxygen atoms, forming SiO₄ tetrahedra connected to each other at the corners. An oxygen atom which connects two tetrahedra is known as a bridging oxygen. An oxygen atom joined to only one silicon atom is a non-bridging oxygen and its one remaining negative charge is satisfied by bonding to a network-modifying cation, such as a univalent sodium ion (Na⁺) if that is the modifier, which occupies an interstice adjacent to the SiO₄ tetrahedron. This corner-sharing tetrahedral structure achieves a randomness, rather than a crystalline regularity, because there is a bending of the Si-O-Si bond at the bridging oxygen. Silica is not the only oxide that fills a network-forming function in glass. Other network-forming oxides are the oxides of boron (13³⁺), germanium (Ge⁴⁺), and phosphorus (P⁵⁺). Examples of network-modifying oxides are those of the alkali ions lithium (Li⁺), sodium (Na⁺), potassium (K⁺), rubidium (Rb⁺), and cesium (Cs⁺) and of the alkaline-earth ions magnesium (Mg²⁺), calcium (Ca²⁺), strontium (Sr²⁺), and barium (Ba²⁺). The oxides of other groups such as lead oxide (PbO), alumina (aluminium oxide; Al₂O₃) often act as intermediates. A target layer can be any material which when exposed to incident radiation produces a plasma comprising ions capable of implanting into the substrate. Examples of target layers include tellurium-based glass. The first target may comprise a glass comprising Lanthanide ions and said ablated material from the first target comprises Lanthanide ions. The second target may comprise a glass comprising Lanthanide ions and said ablated material from the second target comprises Lanthanide ions. The lanthanide ion, for a particular target, may be an ion from amongst the following: erbium, ytterbium, neodymium, praseodymium, holmium, cerium, yttrium, samarium, europium, gadolinium, terbium, dysprosium or lutetium, holmium.

The first target and/or the second target preferably comprises a tellurium-based glass, or a chalcogenide-based glass, or a germanium-based glass, or a bismuth-based glass or a silicon-based glass, or phosphate glass.

The laser is preferably a Femtosecond laser.

The process may include ablating said first and/or said second target with said incident radiation comprising femtosecond laser pulses of peak intensity not less than the threshold laser ablation intensity of the target material. This may include ablating said first and/or said second target with said incident radiation comprising femtosecond laser pulses of peak intensity not less than: about 10^{11wicm2;} or about 10^{12W/}cm^{2;} such as about 1×10¹³ W/cm².

The process may include ablating said first and/or said second target with said incident radiation comprising femtosecond laser pulses defining a focal spot upon said target or a laser beam thereat having a spotsize (e.g. full-width-at-half-maximum, FWHM) of (or up to) about 50pm, or about 40 pm, or about 30pm.

The process of ablation may be done using a laser which may be an ultrafast laser, such as an attosecond, femtosecond or picosecond laser. In one embodiment the ultrafast laser is a femtosecond laser.

The laser may be, for example, a Ti-sapphire laser, a diode pumped laser such as a Yb-doped or Cr-doped crystal laser ora fibre laser.

The laser may be an excimer laser or an exciplex laser.

The laser may be an ultrafast pulsed laser.

In the process of the invention, the laser may emit pulses of about 500ps or less for example pulses in the range about 1fs to about 500ps. In one embodiment in the process of the invention the ultrafast laser emits pulses of about 150fs or less, for example in the range about 50 fs to about 150 fs, for example about 100fs, or for example pulses in the range about 1 fs to about 15 ps.

The pulses may be emitted with a repetition rate in the range about 1Hz to about 100 MHz, or in the range about 250 Hz to about 10kHz. In one embodiment about 400Hz to about 800 kHz, for example about 500kHz.

The laser may be mode-locked.

The average power of the laser may be about10 mW or higher. The average power of the laser may be about 80W or less.

The pulse energy is typically in the range about 10 to about 400 micro joules, or preferably about 10 to about 200 micro joules, or more preferably about 40 to about 150 micro joules, or yet more preferably about 40 to about 80 micro joules, for example about 50 to about 70 micro joules, such as about 65 micro joules.

Pulse energy may be selectively adjusted using an attenuator.

In one embodiment wavelength is typically about 800 nm, although a wide range of wavelengths would be suitable, for example from about 700 nm to about 2500 nm range.

The incident radiation may be incident on a given target material at an angle in the range about 0° to about 80° , or about 40° to about 80° , for example about 60°.

The duration of the process may be about 1 minute or more, for example about 30 minutes to about 10 hours, such as about 2 hours to about 8 hours. In one embodiment the duration is about 6 hours.

The ion-implanted layer may have a substantially uniform distribution of the implanted ions substantially from the surface of the substrate. The applicants have found that the process provides a substantially uniform distribution density of the implanted ions (from both the first and second target materials) in the implanted layer rather than the density profile showing a peak followed by a drop off in implanted ion density, in a manner which the ion depths transcend conventional diffusion and high-energy ion implantation, due to major structural barriers for ion diffusion/implantation.

The applicants have also found that the process provides a very rapid and substantially discontinuous termination in the distribution density of the implanted ions at the terminal boundary of the implanted layer within the substrate, rather than the density profile showing a gradual and continuous drop-off in implanted ion density.

The ion distribution, or concentration level, may fall from the average (e.g. substantially uniform) level of the layer to a substantially ion-free concentration level or distribution, over a distance of about 50 nm or less, or about 30 nm or less, or more preferably about 20 nm or less or yet more preferably about 10 nm or less. This enables a sharply-defined inner terminal “edge” to be formed between the implanted layer and substrate material.

Thus, according to a further aspect of the invention there is provided a substrate comprising an ion-implanted layer wherein the ion implanted layer has a substantially uniform distribution of the implanted ions. Substantial uniformity may be along the transverse and horizontal sections/directions, both in the direction across the implanted substrate surface and transverse to it (i.e. into the surface). The substantial uniformity in the ion distribution may manifest itself as a substantially uniform implanted ion concentration level that varies by no more than +/−10% about the average ion concentration level of the layer as a whole, or more preferably by no more than +/−8%, or yet more preferably by no more than +/−5% about the average ion concentration level of the layer as a whole. This variation may be quantified in terms of a standard deviation value of the ion concentration level. The ion-implanted layer may have an implanted ion density of at least about 10²¹ ions cm⁻³, or at least about 10²³ ions cm⁻³ The penetration depth of the implanted ions may be at least about 50 nm, or at least at least about 200 nm, or at least at least about 500 nm, or at least about 1, or more than 1 μm (e.g. between about 1 μm and about 5 μm, such as between about 3 μm and about 5 μm, e.g. about 3.5 μm). The depth/thickness of the layer containing the implanted ions, within the substrate, may be between about one atomic layer deep to about 10 nm (or about 100 nm), or up to about 5 μm deep, or deeper/thicker.

The process may be conducted in a vacuum chamber. The ablating of material from said first and second targets is preferably done in the presence of a gas at a pressure of about 60 mTorr, or about 80 mTorr, or about 100 mTorr, or about 120 mTorr, or about 200 mTorr. The pressure may be within the range of about 50 mTorr to about 1Torr, or about 50 mTorr to about 500 mTorr, or about 60 mTorr to about 250 mTorr, or about 60 mTorr to about 150 mTorr, or about 70 mTorr to about 150 mTorr, or within the range about 80 mTorr to about 150 mTorr, or at least 80 mTorr (e.g. and up to about 250 mTorr or 500 mTorr or 1 Torr).

The gas may be an inert gas. The gas may preferably be oxygen. The pressure may be a partial pressure.

The substrate may be spaced from the target material by a distance in the range about 1 mm to about 200 mm, or by a distance in the range about 50 mm to about 150 mm, or by a distance in the range about 60 mm to about 100 mm, such as about 70 mm or about 80 mm, or in the range about 20 mm to about 60 mm, such as about 40 mm or about 50 mm.

In a second of its aspects, the invention may provide a substrate comprising an ion-implanted layer containing implanted ions (such as a transition metal, e.g. Lanthanide, e.g. Ytterbium) mixed with different implanted ions (such as a transition metal, e.g. Lanthanide, e.g. e.g. Erbium) with an ion (such as a transition metal, e.g. Lanthanide, e.g. Erbium) density of at least about 10¹⁵ ions cm⁻³, or at least about 10²² ions cm⁻³, or at least about 10²³ ions cm⁻³.

In a third aspect, the invention may provide a substrate comprising a photo-luminescent ion-implanted layer containing implanted ions (such as a transition metal, e.g. Lanthanide, e.g. Ytterbium) ions mixed with different implanted ions (such as a transition metal, e.g. Lanthanide, e.g. Erbium) ions and having a photo-luminescence lifetime-density product of at least about 9×10¹² seconds/cm³, or at least about 9×10¹⁸ seconds/cm³, or at least about 1×10¹⁹ seconds/cm³, or at least about 1.25×10¹⁹ seconds/cm³, or at least about 1.5×10¹⁹ seconds/cm³.

In a fourth aspect, the invention may provide a substrate comprising a photo-luminescent ion-implanted layer containing implanted ions (such as a transition metal, e.g. Lanthanide, e.g. Ytterbium) mixed with different implanted ions (such as a transition metal, e.g. Lanthanide, e.g. Erbium) wherein the penetration depth of the implanted ions is at least an atomic layer thick, or at least 10 nm, or at least about 50 nm, or at least at least about 200 nm, or at least at least about 500 nm, or at least about 1 μm, or more than about 1 μm (e.g. between about 1 μm and about 3 μm), or more than about 5 μm.

According to the second to fourth aspects, the ion implanted layer may have a substantially uniform distribution of the implanted ions substantially from the surface of the substrate. The penetration depth of the implanted ions may be at least an atomic layer thick, or at least an atomic layer thick, or at least about 10 nm, or at least about 50 nm, or at least at least about 200 nm, or at least at least about 500 nm, or at least about 1 μm, or more than about 1 pm (e.g. between about 1 pm and about 3 pm), or more than about 5 μm. The ion (such as a transition metal, e.g. Lanthanide, e.g. Erbium) density may be at least about 10¹⁵ ions cm⁻³, or may be at least about 10²² ions cm⁻³, or at least about 10²³ ions cm⁻³.

The substrate according to any of the second to fourth aspects of the invention may comprise the ion-implanted layer which is either (i) on an outside face of the substrate, or (ii) within the substrate. The ion-implanted layer may either (i) encompasses substantially the whole area of the substrate, or (ii) comprises one or more zones. One or more of the zones may overlap.

The ions (such as a transition metal, e.g. Lanthanide: e.g. Erbium, Ytterbium) described above are preferably cations (e.g. Er³⁺, Yb³⁺).

In a fifth aspect, the invention may provide a waveguide comprising a substrate as described above.

In a sixth aspect the invention may provide an optical component comprising a substrate or a waveguide according to any preceding claim and providing an optical gain per unit length exceeding about 5 dB/cm, or exceeding about 10 dB/cm, or exceeding about 20 dB/cm, or exceeding about 40 dB/cm, or exceeding about 50 dB/cm, or exceeding about 60 dB/cm, or exceeding about 70 dB/cm, or exceeding about 80 dB/cm, or exceeding about 90 dB/cm, such as up to about 100 dB/cm. For example, an ion density of about 1×10²² ions/cm³ translates to a gain of about 100 dB/cm.

According to a further aspect of the invention, there is provided a substrate comprising an ion-implanted layer wherein the ion implanted layer extends substantially from the outermost surface of the substrate. The ion-implanted layer may have a substantially uniform distribution of the implanted ions (from both target materials) extending into the substrate from its outermost surface. This differs from existing ion implanted layers which are formed by firing energetic ions into a substrate to form a buried layer existing some significant distance below the surface of the substrate. Ion implantation extending to the surface of the substrate has advantages including the direct formation of surface optical structures such as regions of increased refractive index and/or waveguide structures in the substrate (e.g. a photonic circuit pattern). The process facilitates ion-implantation to a higher density than prior art processes.

In conventional processes, the achievable densities are an order magnitude less. This specific ability to achieve remarkably high ion concentrations permits bespoke surfaces which have been unachievable in the past for light guiding applications. Such an approach also control of the dielectric and spectroscopic properties in the implanted layer. For example, the implanted layer may be doped with rare-earth ions for engineering lasers and amplifiers, but also be vertically integrated with relevant mirrors and photo-active/sensitive materials, e.g. a metal, polymer, semiconductor, ferro-electric ceramic for frequency conversion and manipulation, a biological surface with a protein. A multitude of optically active and passive functions may be achievable via a combination of chemically dissimilar materials on to a dielectric surface (glass, polymer and ceramic).

According to a further aspect of the invention there is provided a substrate comprising an ion-implanted layer wherein
(i) the ion implanted layer has a substantially uniform distribution of the implanted ions;
(ii) wherein the penetration depth of the implanted ions is at least one atomic layer thick, or at least about 10 nm, or at least about 50 nm or at least about 200 nm, for example at least about 500 nm, or at least about 1 μm such as between about 1 μm and about 3 μm, or about 5 μm or more.

According to a further aspect of the invention there is provided a substrate comprising an ion-implanted layer wherein
(i) the ion implanted layer has a substantially uniform distribution of the implanted ions; and
(ii) the implanted ion density is at least about 10¹⁵ ions cm⁻³, or at least about 10¹⁸ ions cm⁻³ (e.g. 10²¹ ions cm⁻³ or more, such as about 10²³ ions cm⁻³).

According to a further aspect of the invention there is provided a substrate comprising an ion-implanted layer wherein
(i) the penetration depth of the implanted ions is one atomic layer thick, or at least about 10 nm, or at least about 50 nm or at least about 200 nm, for example at least about 500 nm, or at least about 1 μm such as between about 1 μm and about 3 μm, or about 5 μm or more; and
(ii) the implanted ion density is at least about 10¹⁵ ions cm⁻³, or at least about 10¹⁸ ions cm⁻³ (e.g. 10²¹ ions cm⁻³ or more, such as about 10²³ ions cm⁻³).

According to a further aspect of the invention there is provided a substrate comprising an ion-implanted layer wherein
(i) the ion implanted layer has a substantially uniform distribution of the implanted ions;
(ii) wherein the penetration depth of the implanted ions is one atomic layer thick, or at least about 10 nm, or at least about 50 nm or at least about 200 nm, for example at least about 500 nm, or at least about 1 μm such as between about 1 μm and about 3 μm, or about 5 μm or more; and
(iii) the implanted ion density is at least about 10¹⁵ ions cm⁻³, or at least about 10¹⁸ ions cm⁻³ (e.g. 10²¹ ions cm⁻³ or more, such as about 10²³ ions cm⁻³).

The penetration depth of the ion layer depends on the substrate used but in general would be one atomic layer thick, or at least about 10 nm, or at least about 50 nm or at least about 250 nm, at least about 300 nm, at least about 400 nm, at least about 500 nm, at least about 750 nm, at least about 1 μm, at least about 1.5μm, at least about 2.0 μm, at least about 2.5 μm and at least about 3 μm, or about 5 μm or more. In one embodiment the layer has a depth from about one atomic layer thick, or at least about 10 nm to about 3 μm, for example in the range about one atomic layer thick, or at least about 10 nm to about 2.5 μbout one atomic layer thick, or at least about 10 nm to about 2 μbout one atomic layer thick, or at least about 10 nm to about 1.5 μm or about one atomic layer thick, or at least about 10 nm to about 1 μm. In a further embodiment the layer has a depth from about 500 nm to about 3 μm, for example in the range about 500 nm to about 2.582 m, about 500 nm to about 2 μm, about 500 nm to about 1.5 μm or about 500 nm to about 1 μm, or about 3μm, or about 5 μm or more.

In general the implanted ion density may be at least about 10¹⁵ ions cm⁻³, or at least about 10¹⁶ ions cm⁻³ may be up to about 10²³ ions cm⁻³ (e.g. in silica glass), for example about 5×10²¹ ions cm⁻³.

The ion implanted layer may comprise one or more different ions.

The implanted layer can encompass substantially the whole area of the substrate or can comprise one or more zones (e.g. optical waveguide path patterns). The zones may comprise distinct areas on or within the substrate or one or more of the zones may overlap. The zones may comprise the same ion or ions or one or more of the zones may comprise a different ion or ions.

The ion may be a cation.

The ion may be selected from any cation which is ionisable, for example one or more of the following groups:
(i) one or more transition metals ions, and/or pre-lanthanide and/or lanthanide ions;
(ii) erbium, ytterbium, neodymium, praseodymium, holmium, cerium, yttrium, samarium, europium, gadolinium, terbium, dysprosium, holmium or lutetium ions;
(iii) Nd³⁺, Yb³⁺, Er³⁺, Tm³⁺, Pr³⁺, Ho³⁺, Sm³⁺, Eu³⁺, Tb³⁺ and Ce³⁺, La³⁺, Gd³⁺, Dy^{3 +} ions;
(iv) tellurium, germanium, zinc, sodium and erbium ions;
(v) metallic ions: for example, Bi, W, Nb, Ta, Ti, Mo, Cr, Mn, Ga, In, Sn, Pb, Au, Ag, Al, Fe, Co;
(vi) one or more one or more actinide ions;
(vii) actinium, americium, berkelium, californium, curium, einsteinium, fermium, lawrencium, mendelevium, neptunium, nobelium, plutonium, protactinium, thorium and uranium,
(viii) one or more transition metals;
(ix) One or more anions which may be of F, Cr, BC, I, and chalcogen ions (S and Se);
(x) one or more cations selected from the groups (i) to (ix) above.

The silicon-based substrate may comprise silicon, glass, silicon oxide (e.g. SiO₂ or other oxide) or silicon hydride, siloxane polymer, or silicon nitride, or silicon-germanium or silicon carbide.

In a further embodiment the silicon-based substrate may be a glass. Examples of glass include: silica, silicate, phosphate, tellurite, tellurite derivatives, germanate, bismuthate, borates, acetates, halides, chalcogenides and solgel route glasses.

The polymeric substrate may comprise Poly(methyl methacrylate) (PMMA), polyvinyl alcohol (PVA), polyether ether ketone (PEEK), polyethylene terephthalate (PET), polyimide(PI), polypropylene (PP), and polytetrafluoroethylene (PTFE), Polydimethoxy Siloxane (PDMS).

Novel ion-implanted substrates of the invention have application in a number of technologies, for example, in communication, computer or display technology, solidstate lighting and in laser assemblies. The novel ion-implanted substrate of the invention may be used in integrated optics (eg as a signal source, amplifier, wavelength splitter etc), chemical sensing, environmental sensing, bio-sensing, micro-nano spectroscopy, optical communication, micro fluidic devices, opto-fluidic devices, terahertz amplifiers, lab-on-chip or optical tomography.

The novel ion-implanted substrate of the invention may be used as a waveguide.

In one embodiment of the invention there may be provided a waveguide comprising an ion-implanted substrate of the invention. Examples of optical waveguides include: slab waveguides, planar waveguides, optical fibres and other waveguides such as would be apparent to the skilled person.

The wavelength range of fluorescence of the substrate, or in a device (e.g. a chip) comprising a substrate, of the invention is governed by the ion which are implanted into the substrate. The skilled man would be familiar with the spectral properties of suitable doping ions and therefore chose the appropriate ions for preparing an ion-implanted substrate with suitable spectral properties.

Example of the spectral properties include:
(i) 950-1200 nm Yb;
(ii) 1500-1650 nm range Er;
(iii) 1400-1530 and 1600-2200 Thulium;
(iv) 1900-2500 nm Ho;
(v) 1750 nm-2200 nm co-doping with Tm and Hoions;
(vi) 950 nm-2500 nm co-doping with Yb, Er, Tm and Ho;
(vii) 2000-4500 nm Dy/Tb/Er

The substrate may have a thickness in the range of about 0.1 mm to about 10 mm, such as in the range of 0.5 mm to about 3 mm, e.g. when used in waveguides of the invention. The substrate may be a thin layer (e.g. with a thickness of about 50 nm or more) of one or more of the following materials arranged or formed upon on any solid material e.g. a support material: silica, silicate, phosphate, tellurite, tellurite derivatives, germanate, bismuthate, borates, acetates, halides, chalcogenides and solgel route glasses. The laser may be arranged to input light at an end, side or edge of the substrate (e.g. waveguide) such that the laser light is guided along the substrate internally to the ion implanted substrate.

The process may further comprise employing one or more masks/stencils to facilitate implantation of ions in specific zones of the substrate, e.g. ion implantation through the mask/stencil to form/‘print’ a desired pattern, e.g. to generate an optical waveguide or other fine pattern printing, for example, on suitable substrates and/or surfaces.

In a further embodiment of the invention there is provided a process for making an ion-implanted substrate of the invention comprising:
(i) providing a first target material;
(ii) providing a second target material comprising material not comprised in the first target material;
(iii) providing a substrate in proximity to said first target material and said second target material; and
(iv) directing incident radiation from a laser (e.g. a pulsed laser, such as an ultrafast laser) at the first target material and at the second target material to produce an ion-comprising plasma respectively from each of the first and second target materials whereby ions from each said plasma reach the substrate at different respective times and are implanted into the substrate.

The process may include controlling the implantation depth of ion implantation within the target layer by controlling any one of, or any combination of the following process parameters: the pulse repetition rate of the pulsed laser; the laser pulse energy; laser beam or focal spot intensity; the duration of application of the process of implantation (e.g. the implantation time). The method may include selectively increasing (or decreasing) any one or more of these process parameters to increase (or decrease) the implantation depth. The process may include controlling the value of the refractive index of the ion-implanted region within the target layer by controlling any one of, or any combination of the following process parameters: the pulse repetition rate of the pulsed laser; the laser pulse energy; laser beam or focal spot intensity; the duration of application of the process of implantation (e.g. the implantation time). The method may include selectively increasing (or decreasing) any one or more of these process parameters to increase (or decrease) the value of the refractive index of the ion-implanted region. Any variation/alteration in one such process parameter may be performed whilst holding one or all of the other process parameters substantially constant, or whilst also varying/altering one or all of the other process parameters.

The term ‘about’ when used in this specification refers to a tolerance of ±10%, of the stated value, i.e. about 50% encompasses any value in the range 45% to 55%, In further embodiments ‘about’ refers to a tolerance of ±5%, ±2%, ±1%, ±0.5%, ±0.2% or 0.1% of the stated value.

The term ‘dopants’ refers to ions implanted into a substrate. Dopants include ions implanted into substrates of the invention.

The term ‘glass’ refers to a solid that possesses a non-crystalline (i.e., amorphous) structure and that exhibits a glass transition when heated towards the liquid state and which transmits light in the infrared, visible or ultraviolet spectrum, i.e. a wavelength of about 10 nm to 300 μm. In one embodiment ‘glass’ refers to a glass which transmits light in the visible spectrum i.e. a wavelength of about 380 nm to about 740 nm. In a further embodiment ‘glass’ refers to a glass which transmits light in the infrared spectrum i.e. a wavelength of about 740 nm to about 300 μm. In a further embodiment ‘glass’ refers to a glass which transmits light in the ultraviolet spectrum i.e. a wavelength of about 10 nm to about 380 nm. In a yet further embodiment ‘glass’ refers to a glass which transmits light in the wavelength range about 400 nm to about 2000 nm.

The term ‘glass softening point/temperature’ refers to a temperature of a material where the material softens to become deformable. Preferably, it refers to the temperature such as may be determined according to ASTM standard C338. This standard is available from ASTM International, 100 Barr Harbour Drive, PO Box C700, West Conshohocken, Pa. 19428-2959, USA.

The term ‘glass transition temperature’ refers to a temperature within the ‘glass transition range’ of a material where the material undergoes a transition between a glass and a super-cooled liquid. It is sometimes referred to as the ‘fictive temperature’.

Preferably, it refers to the temperature such as may be determined according to ASTM standard E1356: “Standard Test Method for Assignment of the Glass Transition Temperatures by Differential Scanning calorimetry”, using the ‘midpoint temperature’ (Tₘ) defined therein to represent the glass transition temperature (T_{g}). This standard is available from ASTM International, 100 Barr Harbour Drive, PO Box C700, West Conshohocken, Pa. 19428-2959, USA.

The term ‘implantation’ refers to ion entering the matrix of the substrate rather than forming a film on the surface of the substrate.

The term ‘optical polymer’ refers to any polymer which transmits light in the infrared, visible or ultraviolet spectrum, i.e. a wavelength of about 10 nm to 300 μm. In one embodiment ‘optical polymer’ refers to a polymer which transmits light in the visible spectrum i.e. a wavelength of about 380 nm to about 740 nm. In a further embodiment ‘optical polymer’ refers to a polymer which transmits light in the infrared spectrum i.e. a wavelength of about 740 nm to about 300 μm. In one embodiment ‘optical polymer’ refers to a polymer which transmits light in the ultraviolet spectrum i.e. a wavelength of about 10 nm to about 380 nm. In a yet further embodiment ‘optical polymer’ refers to optical polymers which transmits light in the wavelength range about 400 nm to about 2000 nm.

The term ‘substrate’ includes a reference to a silicon-based substrate (e.g. comprising a silicon compound) or a polymeric substrate, for example, a material selected from glass or an optical polymer or a combination of these materials.

The term ‘waveguide’ refers to any element which facilitates transmission of light therethrough, such as guided transmission. The term includes a reference to any element which facilitates transmission of light into a material of interest and facilitates measurement of light which is retrieved from the material of interest.

The invention will now be illustrated with the following non-limiting examples with reference to the following figures.

### DRAWINGS

FIG. 1 shows schematically the ablation, plasma production and the multi-ion implantation process.

FIG. 2A shows schematically the ablation, plasma production and the multi-ion implantation process according to a sequential ablation of two differently-doped target glasses.

FIG. 2B shows schematically the ablation, plasma production and the multi-ion implantation process according to a single ablation of one co-doped target glass.

FIG. 3a shows a view of an ion-implanted layer in a silica substrate made according to a sequential ablation of two differently-doped target glasses of FIG. 2A.

FIG. 3b shows a view of an ion-implanted layer in a silica substrate made according to a single ablation of one co-doped target glass of FIG. 2B.

FIG. 3c shows a view of an ion-implanted layer in a silica substrate of FIG. 3a, at higher magnification.

FIG. 4 shows an electron microscope image of an ion diffused layer within a silica glass, together with respective SAED patterns.

FIGS. 5 represents a schematic diagram of an ion-implanted silica later (top) and an EXD mapping from cross-sectional TEM analysis of an actual ion-implanted silica later (bottom), such as shown in FIG. 3a.

FIGS. 6 represents a PP-TOFMS profile of an ion-implanted silica later (bottom), such as shown in FIG. 5.

FIG. 7a shows atomic concentrations as a function of implantation depth of an ion-implanted silica later such as shown in FIG. 3a.

FIG. 7b shows atomic concentrations as a function of implantation depth of an ion-implanted silica later such as shown in FIG. 3b.

FIG. 8a shows the RBS spectra of an ion-implanted silica later such as shown in FIG. 3a.

FIG. 8b shows the RBS spectra of an ion-implanted silica later such as shown in FIG. 3b.

FIG. 9a shows the refractive index profile of an ion-implanted silica later such as shown in FIG. 3a.

FIG. 9b shows ellipsometric data from an ion-implanted silica later such as shown in FIG. 3b.

FIG. 9c shows light transmittance data from an ion-implanted silica later such as shown in FIG. 3a.

FIG. 10 shows the variation of density in a target glass (i.e. the ablated target glass) as a function of rare-earth ion concentration.

FIG. 11a shows the PL intensity spectrum for an ion-implanted silica later such as shown in FIGS. 3a, and 3b.

FIG. 11 b shows the PL profile for an ion-implanted silica later such as shown in FIGS. 3a, and 3b.

FIG. 12 shows the variation of PL lifetime of an ion-implanted silica later such as shown in FIGS. 3a (left-hand axis of graph) and of doped target glass, as a function of target glass dopant concentration.

FIG. 13 shows the variation in implanted ion layer depth/thickness (measured from the surface of a substrate e.g. “waveguide” containing the implanted layer) and refractive index of that layer, as a function of target glass dopant concentration;

FIG. 14 schematically shows an apparatus and procedure for implementing the manufacture of a substrate according to a preferred embodiment.

### ABBREVIATIONS USED

HAADF high angle angular dark field elemental mapping
NIR near infra red
SEM Scanning electron microscopy
TEM Transmission electron microscopy
HRTEM High-resolution cross-sectional transmission electron microscopy
RBS Rutherford back-scattering spectrometry
SIP System in package
DWDM Dense wavelength division multiplexing
PL Photoluminescence lifetime
ADTS Erbium-doped tellurite-modified silica
SAED Selected area electron diffraction
FWHM Full width at half maximum
RETS Rare-earth doped tellurite modified silica

### DETAILED DESCRIPTION

### EXAMPLE

### Implantation into Silica Glass

Highly rare-earth doped silicates have potential to provide advances in optical and photonic applications and devices. However, the limited solubility of rare-earth ions in silica hampers this.

The present invention, in preferred embodiments such as the embodiment described below, provides a novel method of producing a hybrid material comprising the integration of rare-earth doped (e.g. Lanthanide) silica substrate or chalcogenide glass substrate (e.g. a glass containing selenium or tellurium). This has been found to provide significantly high doping concentration of rare-earth dopant ions (e.g. Er³⁺ and Yb³⁺, for example, though not limited to these), without segregation. This has been validated by the provision of a remarkably high value of the standard metric: the lifetime-density product', of 1.49×10¹⁹ s.cm⁻³.

This embodiment illustrates the invention in terms of the sequential ablation of two individual rare-earth (Er³⁺/Yb³⁺) doped-tellurite glass targets. However, as discussed above, the invention applies equally to other dopant ions (not just Lanthanides), to other target glasses (not just tellurite glasses e.g. chalcogenide glass) and to other substrate materials (not just silica), and to equivalent non-sequential ablation of the two different target materials (provided that sequential arrival of ion plumes at the substrate is achieved, as discussed above).

As a means of better illustrating the remarkable, and unexpected, effects achieved by sequential ablation (or its equivalent) of different target materials, a tandem experiment is described for comparison in which a single co-doped Er³⁺-Yb³⁺-tellurite target glass was ablated alone for the ion-implantation of an otherwise identical silica substrate. The two-target sequential ablation processes accomplished a rare-earth concentration of 0.89×10²¹ cm⁻³, demonstrating an Er³⁺:⁴I_{13/2} PL lifetime of 12.9 ms. The twin-target sequential processes led to the formation of a cluster-less, continuous and homogeneous tellurite modified silicate layer, confirmed by cross-sectional transmission electron microscopy and plasma profiling time-of-flight mass spectrometry analysis.

An exceptional intermixing of Er³⁺and Yb³⁺ ions extending to the pristine silica substrate is achieved via the sequential two-target ablation (therefore, sequential doping) method. Moreover the unique sequential ablation (doping) process achieved a 30% higher planar optical layer thickness and 35% longer fluorescence lifetime as compared to the co-doped single-target comparison sample.

These results indicate that the sequential ablation/doping approach is better than the single co-doped target process for fabricating thicker rare-earth-doped (e.g. Er³⁺-Yb³) lanthanide-modified silicate layers (e.g. tellurite glass, or chalcogenide glass etc., alternatively). It is postulated that this process enables the substrate matrix to maintain the larger distance between the dopant ions, which is highly preferable for lowering fluorescence quenching.

Rare-earth (RE) doped silicates have been widely explored as an amplifying media for the optical communication systems. For example, the intra-4f transition ⁴I_{13/2→}⁴I_{15/2} in erbium (Er³⁺) ions matches the C+L-band communication wavelength (1530-1605 nm), which makes them attractive for optical amplifier and laser applications. In erbium-doped fiber amplifiers (EDFAs), long lengths of fibers (>5 m) are required to achieve 20 dB optical gain, this long length requirement is due to the limited solubility of rare-earth ions (e.g. Er³⁺) ions in silica. This low optical gain per unit length makes miniaturisation very difficult. Thus, loss-compensation is required. In this respect high-gain erbium-doped waveguide amplifiers are highly desirable. Erbium chloride incorporated silicates can have Er³⁺ ion density of up to 10²² cm⁻³, however the metastable lifetime of the ion is much too short. This is due to the phenomena of concentration quenching, where the physical limits of ion-ion interactions are reached, assisting macroscopic energy transfer at the ⁴I_{13/2} energy level.

The invention, as illustrated by the present non-limiting embodiment, enables rare-earth (e.g. Er³⁺) ions to be incorporated into a substrate (e.g. silica) at much higher concentrations (≥10²¹ cm⁻³) without concentration quenching and shortening of the metastable lifetime at the ⁴I_{13/2} energy level. In addition, the invention in its preferred embodiments is able to incorporate a different rare-earth ion (e.g. Yb³⁺) ion for enhancing pump absorption via the ²F_{7/2}→²F_{5/2} transition over a short distance. This allows the efficient inversion of one species of rare-earth ion (e.g. Er³⁺ ions) via resonant energy transfer using the other species of rare-earth ion (e.g. from Yb³⁺:²F_{5/2}→Er³⁺:⁴I_{13/2}).

This assists in increasing the mean inter-atomic distance to minimize the ion-ion (e.g. Er³⁺-Er³⁺ ion) energy transfer interactions.

In the following embodiment, it is demonstrated that an unusual rare-earth ion (e.g. Yb³⁺and Er³⁺) mixing in the e.g. a silicate matrix is achieved according to a preferred embodiment of the invention, during fs laser-induced plasma assisted sequential doping process. This method enhances both the modified silicate layer thickness and PL characteristics, as compared to the doping of Er³⁺/Yb³⁺ ions using a single co-doped tellurite target for ablation. The unexpected existence of inter-layer mixing yields remarkable spectroscopic results.

Tellurite glass targets of the following molar percentage concentrations were used, with x=1, but other values of x are equally applicable:

Target (a): (80-x)TeO₂-10ZnO-10Na₂O-xEr₂O₃ (this is the Er-doped target of two targets);

Target (b): (80-x)TeO₂-10ZnO-10Na₂O-xYb₂O₃ (this is the Yb-doped target of two targets);

Target (c): (80-x-y)TeO₂- 10ZnO-10Na₂O-xEr₂O₃-yYb₂O₃ (the single Er/Yb co-doped target).

These were prepared using standard glass melting and quenching processes.

The fs laser plasma assisted doping process was carried out in a vacuum chamber under an oxygen (O₂) atmosphere of 80 mTorr at an optimum processing temperature of 973 K.

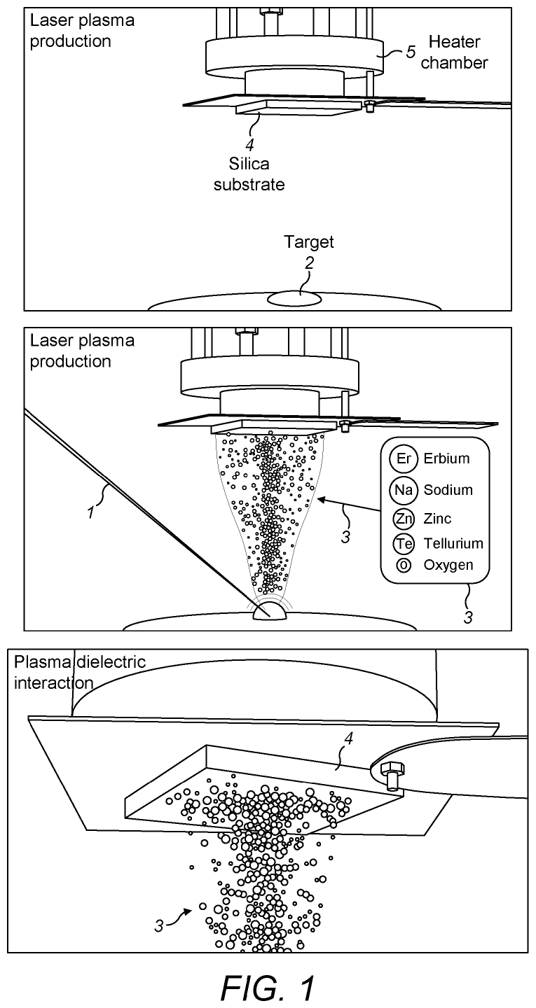

FIGS. 1A, 1B and 1C schematically show the ablation of the tellurite ‘target (a)’ listed above, and it is to be understood that it applies equally to the Yb-doped ‘target (b)’ defined above in which the illustrated ‘Er’ ions are replaced by ‘Yb’ ions, and it applies equally to the Er/Yb co-doped ‘target (c)’ defined above in which the illustrated ‘Er’ ions are joined by ‘Yb’ ions. In particular, referring to FIG. 1A and 1B, multi-ion implantation into silica glass 4 was produced via femtosecond pulsed laser ablation of the relevant glass target. A femtosecond pulsed laser 1 was used to ablate the glass target 2 thereby generating an expanding plasma plume 3 consisting of multiple metal ions (multi-ion). The glass target produces multiple ions of Te, Zn, Na and Er, and/or Yb, which diffuse into the silica glass substrate 4 under certain process conditions, as shown in FIG. 1C. The silica glass substrate was coupled to a heater chamber 5 arranged to heat the substrate to a desired temperature. The laser source 1 (e.g. Ti-Sapphire laser) was used with a pulse duration of 100 fs, operation wavelength of 800 nm, a pulse repetition rate of 1 kHz and a single pulse energy of 50 μJ and peak intensity of 1×10¹³ W/cm² was used to ablate the targets. The silica glass substrate 4, measuring 30×20×1 mm (width×length×thickness), was positioned 70 mm above and parallel to the tellurite target glass 2 for receiving the ablated high energy plasma plumes 3.

The substrate was heated during this process to a temperature of about 973K (below the glass transition temperature and below the softening point/temperature of silica).

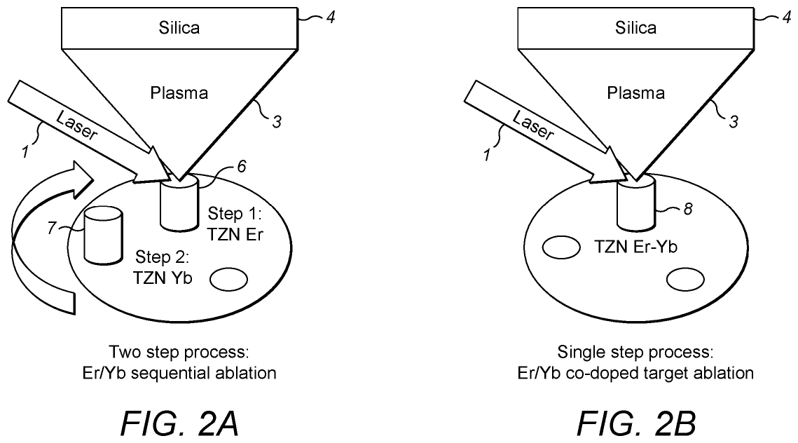

The schematic diagram of FIGS. 2A and 2B show the procedural differences in the fabrication of different Er³⁺-Yb³⁺-tellurite modified silica layers using: (FIG. 2A), the sequential ablation and doping of Er³⁺and Yb³⁺tellurites into silica using a two separate target glasses (7, 8) ‘target (a)’ 6 and ‘target (b)’ 7, and; (FIG. 2B) the single-step, single-target process of ablating one target glass 8 co-doped with Er³⁺and Yb³⁺and defined above as ‘target (c)’.

The sequential-ablation approach (FIG. 2A) was used to prepare a first ion-implanted test substrate Sample 1 (‘S1’ hereafter). This was done by the initial ablation of the ‘target (a)’ glass 6 first, using the laser 1 for continuous period of two hours. It is to be understood that a different time period may be used, such as little as about a minute, or a up to five minutes, or up to 30 minutes, or up to 60 minutes, or more. After that, substantially without pause (a few seconds or so to allow target change-over) the ablation process was continued using the laser 1 but this time targeting the second ‘target (b)’ glass 7 for the following 2 hours without changing the ambient conditions. It is to be understood that a different time period may be used, such as little as about a minute, or a up to five minutes, or up to 30 minutes, or up to 60 minutes, or more.

Separately, under otherwise materially identical conditions, the single-ablation approach (FIG. 2B) was used to prepare a second ion-implanted test substrate Sample 2 (‘S2’ hereafter). This sample (S2) used only the Er/Yb, co-doped target 8, and was continuously ablated by the laser 1 for a period of four hours under the identical process conditions.

### Structural Characterisation—Methods

The structural characterization of the two resulting substrate samples S1 and S2 was done using transmission electron microscopy (TEM) FEI Tecnai TF20 field emission gun (FEG) TEM (200 kV) fitted with a high angle annular dark field (HAADF) detector; a Gatan SC600 Onus CCD camera (Gatan Inc., Pleasanton, Calif.); and an Oxford Instruments 80mm² X-max SDD energy dispersive X-ray spectroscopy (EDX) detector (Oxford Instruments plc., Abingdon, UK). Rutherford Backscattering Spectrometry (RBS) is a powerful technique for non-destructive compositional analysis of thin layers and nanostructured materials.

In this work, RBS analysis was performed in a scattering chamber with a two-axis goniometer connected to a 5 MV EG-2R Van de Graaff accelerator. The 2820 keV ⁴He⁺ analyzing ion beam was collimated with two sets of four-sector slits to the spot size of 0.5×0.5 mm², while the beam divergence was kept below 0.06°. The beam current was measured by a transmission Faraday cup. Backscattering spectra were detected using an ORTEC surface barrier detector mounted in Cornell geometry (i.e. detector under the beam, with vertical sample rotation axis) at a scattering angle of Θ=165°.

An electron source installed in the sample chamber was used to avoid ion beam-induced charging of the insulating glass samples. In the spectrum recording, a blind detector with a thin Aluminium reflection layer on top was used to avoid light-induced background counts originating from the electron source and from ion beam-induced luminescence of the glass samples. The energy resolution of the detection system was 20 keV. Note, in this work the depth resolution of RBS at the sample surface is about 3 nm, and a poorer value can be considered as a function of depth. Spectra were recorded for sample tilt angles of 7° and 45°. The RBX spectrum simulation has been performed to achieve best fits simultaneously for both tilt angles. The effective thickness of the modified layers was estimated supposing an atomic layer density of silicon dioxide, N=6.5×10²² atom cm⁻³. This value can be calculated from silica glass density measurements resulting in 2.2g/cm³. The relative elemental concentrations in the samples were obtained using plasma profiling time of flight mass spectrometry (PP-TOFMS) by Horiba Scientific, France. PP-TOFMS combines a glow discharge (GD) plasma and an orthogonal time of flight mass spectrometer. The plasma is created in ultra-pure Argon between a grounded electrode and the sample which is powered from its back with a pulsed 13.56MHz RF voltage. The plasma ensures fast and uniform material removal over a 4 mm diameter area from the surface to the bulk and parallel excitation/ionization of the sputtered species. The ultrafast and full mass coverage TOFMS detection is adapted to the fast erosion rate (up to tens of nm/s) of the plasma. Time of Flight (TOF) records a full and continuous mass spectrum in every 30 μs, thereby providing constant monitoring of all the species throughout the depth profile. An instantaneous semi-quantification giving elemental atomic concentrations can be obtained by calculation of Ion Beam Ratios (IBR). The IBR approach is commonly used in glow discharge mass spectrometry (GDMS) and is based on calculating the ratio of ion current for any one isotope with respect to the total ion current except the signal rising from the plasma gas and using the assumption that this ratio is representative of the atomic concentration of that isotope in the sample. A Metricon model 2010 prism coupler at 1550 nm was used to measure the planar optical layer thickness and refractive indices on the silica substrate. The amplitude ratio (IP) and phase difference (A) of the complex reflectance ratios for light polarized parallel and perpendicular to the plane of incidence was measured using a Woollam M-2000D1 rotating compensator spectroscopic ellipsometer. Acquisition of the transmission spectra for these samples was done using PerkinElmer LAMBDA 950 UV/Vis/NIR spectrophotometer. Standard excitation and emission fluorescence of the silicate planar waveguide samples were obtained using an Edinburgh Instruments FLS920 series of spectrometer fitted with a liquid nitrogen cooled photomultiplier tube (PMT) near-infrared (NIR) detector, operating in the 700-1700 nm wavelength range and a JDSU pump laser source operating at a wavelength of 980 nm, respectively. The fluorescence lifetime was also calculated using a time resolved fluorescence spectra, whereby the laser source was pulsed with a 100ms period and a pulse width of 10 μs.

### Structural Characterisation—Results

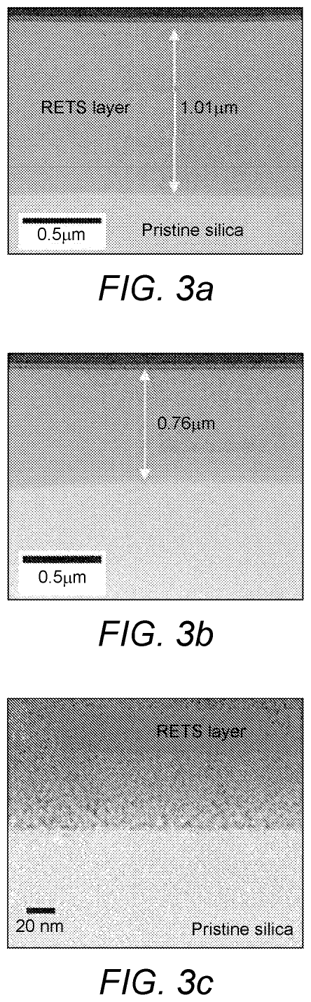

The high resolution TEM cross-sectional images of the samples S1 and S2, as prepared by focused ion beam (FIB) lithography is shown in FIGS. 3(a) and 3(b), respectively. Both the sequential-ablation process (FIG. 2A) and the single-step ablation process (FIG. 2B), described above, result in a homogenous metastable state of rare-earth doped tellurite modified silica (RETS) in the substrate.

A sharp interface between the RETS and pristine silica is obtained through the sequential-ablation process (FIG. 2A) in particular, as is shown in FIG. 3(c) as a high magnification of FIG. 3(a) using a high angle annular dark field (HAADF) cross-sectional image of S1 showing the interface of pristine silica and RETS.

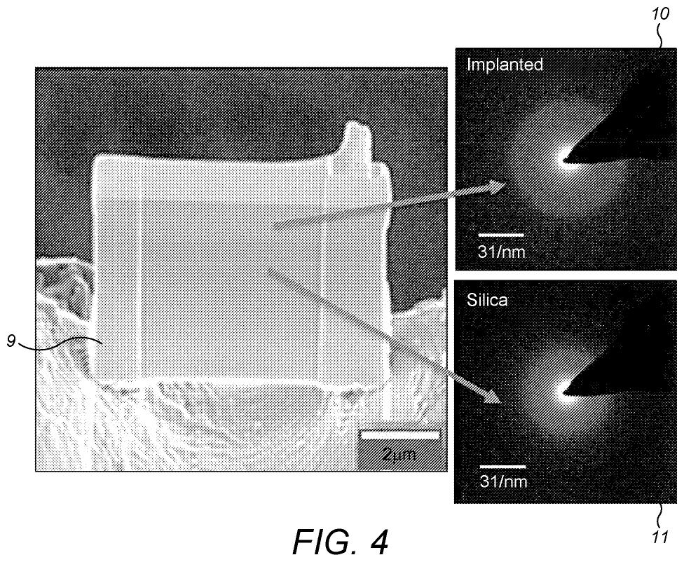

The accompanying selected area electron diffraction (SAED) patterns (10, 11) are shown in FIG. 4. These illustrate SAED patterns generated from the modified RETS layer and pristine silica region from sample S1 (item 9 of FIG. 4). The larger diffraction ring radius of the modified layer implies higher density compared to the pristine silica layer. This demonstrates a typical amorphous nature of both the RETS region and the pristine substrate, respectively, showing a lack of long-range order in the atomic lattice, and exhibiting diffuse ring diffraction patterns without any discrete reflections.

Note the difference in the sizes of diffraction rings in FIG. 4 for the implanted RETS layer 10 and the pristine silica region 11, respectively. It can be clearly seen that the ring radius of the SAED pattern from the RETS layer is larger than in the pristine silica region. It is known that the radius of the ring is inversely proportional to the corresponding inter-atomic spacing in the sample. The average spatial distribution of atoms calculated from the ring radius for the modified site of sample S1 is 1.35 Angstrom, 27% shorter than the pristine silica, measuring 1.86 Angstrom. This indicates that the RETS layer is more closely packed, and therefore of greater density, than the base silica layer. The dense packing is due to the modification of the silica network with heavier tellurium and rare earth ions.

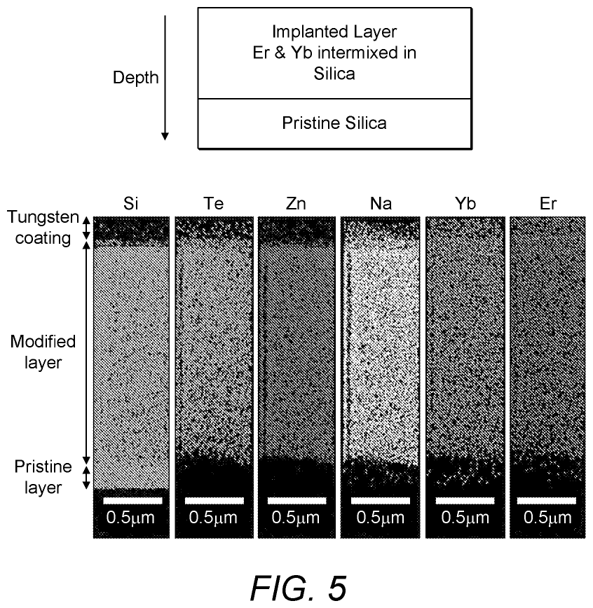

The RETS layer formed by the sequential-ablation approach (FIG. 2A) was further analyzed using energy dispersive X-ray spectroscopy (EDX). Mapping scans of a 1.4 μm thick sample S1 are illustrated in FIG. 5. This reveals, quite remarkably and against all expectation, the generation of a substantially uniform and homogenous mixture of Er³⁺and Yb³⁺ ions extending from the surface of the substrate to a relatively sharp internal ‘edge’ within the substrate defining the bottom of the modified layer. The distribution of various elements (Si, Te, Zn, Na, Yb and Er) in the RETS layer is indicated. Homogenous mixing of Er and Yb is achieved in spite of the sequential ablation of the target glasses in question and the resulting sequential doping of the substrate with ions therefrom.

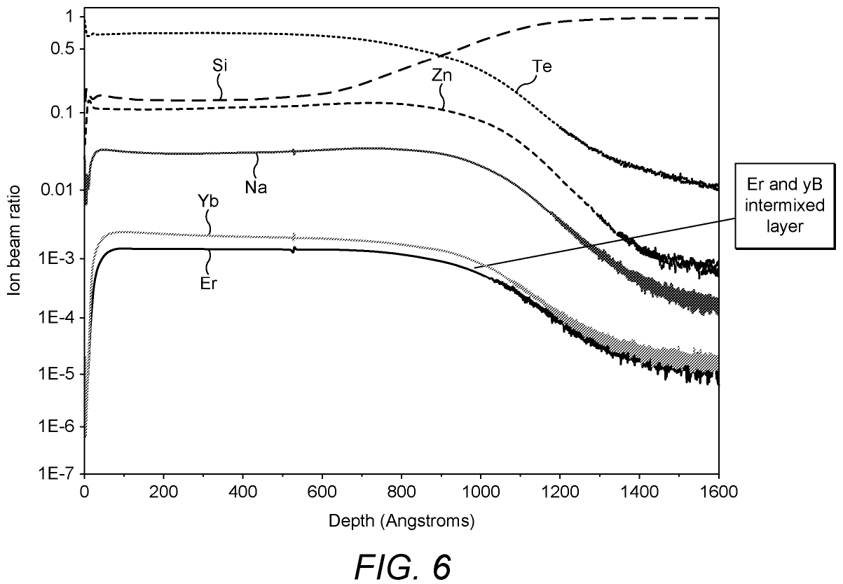

FIG. 6 shows a PP-TOFMS profile of sample S1. Ion beam ratio of the elements in the sample indicates the uniform distribution of Er and Yb within the substrate. In this regard, sample S1 was characterized by plasma profiling time of flight mass spectrometry (PP-TOFMS) for semi-quantification of the elemental concentrations.

It can be seen from FIG. 6 that the tellurite compounds along with rare earth elements are mixed well with silica and the modified layer extends to the pristine silica region.

A silica rich RETS layer with homogeneously distributed Er and Yb is obtained, contrary to what one would expect of sequential ablation.

Based on the EDX mapping and the PP-TOFMS findings, and without being bound by theory, it is postulated the process can be assumed to be controlled by both highly energetic ions in the laser plasma and the high process temperature, 973K (below the glass transition temperature and below the softening point/temperature of silica), that initiates an interfacial reaction between the ablated ions of the target glass and the silica substrate. Above 873K, the alkali metals in the implanted into the silica substrate (Te and Na) attack the silica substrate, enabling the regular dissolution of silica throughout the process. This is thought to result in the formation of a well-defined metastable homogeneous modified ion-implanted layer. A similar phenomenon is also postulated for the subsequently-ablated target material, in which significant intermixing between the implanted ions of the second target (Yb³⁺doped) and of the first target (Er³⁺doped) arises. Consequently a uniform distribution of Er³⁺and Yb³⁺ ions may arise in the form of a single modified layer within the silica substrate, such as can be seen from the elemental maps in FIG. 5.

The evidence implies that even though the Er³⁺ and Yb³⁺ doped tellurites were ablated sequentially, interfacial reactions and intermixing of the implanted ions help the Yb³⁺ doped ions to extend down to the modified-pristine silica boundary, suggesting that over a period of time (e.g. two hours in this example), sufficient ion mobility may be occurring during the process at a substrate temperature maintained at 973K. Such novel nanoscale layer formation, without silica precipitation, is not possible with conventional fabrication methods, and this represents a step-change in materials production.

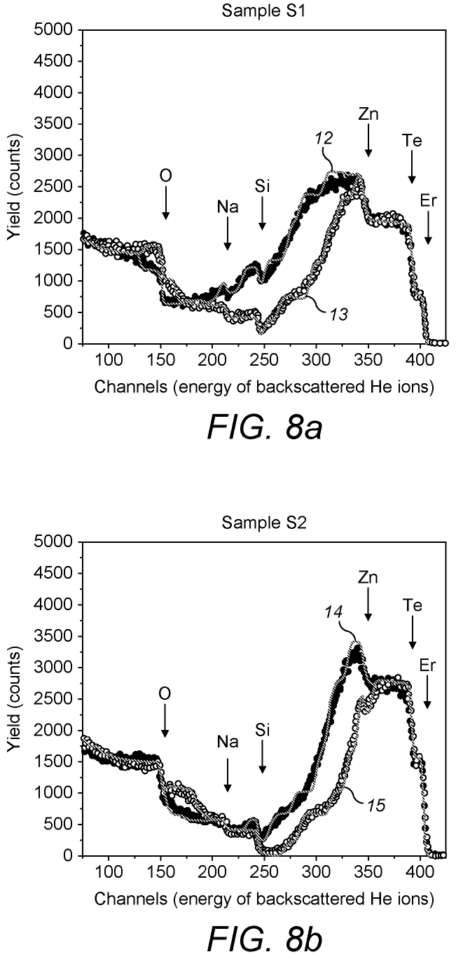

RBS spectra of both samples, S1 and S2, were taken to estimate the atomic composition for O, Si, Na, Zn, Te, and Er/Yb. The sample spectra for S1 and S2, along with their simulations are shown in FIGS. 8(a) and 8(b), respectively. The RBS spectra of the implanted layer/SiO₂ substrate were measured at two different sample tilt angles of 7′ (open dots) and 45° (solid dots), respectively. The corresponding RBX simulations are also shown (underlying solid lines: 12, 13, 14 and 15). Surface spectrum edges for Er, Te, Zn, Si, Na and O are indicated.

RBS cannot distinguish between Er and Yb due to their very similar energy threshold, so the peak corresponding to Er in the RBS spectra indicates both the Yb and Er content together. In FIG. 8(a), the different height of the spectra at channel numbers above 250 is primarily due to the different Er/Yb content. For S2 nearly double height of the Er shoulder can be observed than for S1, revealing about two times higher Er/Yb concentration. The spectrum S1 is significantly wider as it can be observed for the Zn, Te, and Er components (Na and O overlap with the substrate SiO₂ signal). This is the consequence of the thicker modified silica layer (i.e. ion-implanted) for sample S1. The atomic composition and evaluated effective layer thicknesses are summarized in Table 1.

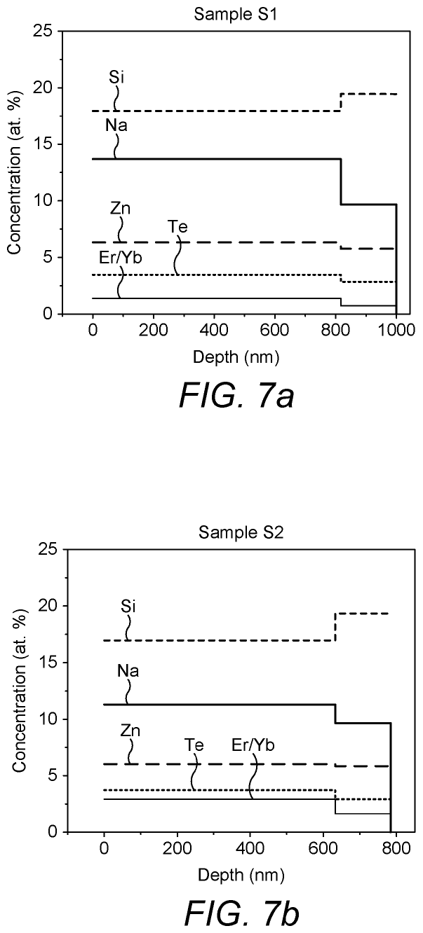

The depth profiles with atomic concentrations of various elements was evaluated from these RBS spectra using a simple two layer model, and these are represented in FIGS. 7(a) and 7(b) for S1 and S2, respectively. The effective thicknesses (‘depth’) of the implanted layers are given in nm, and are recalculated from thicknesses given in atom/cm² (provided by the RBS analysis) assuming the atomic density of silica, respectively, and evaluated from 2.82 MeV He⁺ RBS spectra using a simple two layer model.

TABLE 1
Parameters used in the RBX simulation
of the measured RBS spectra.

| | Implanted layer | | | | | | Implanted | Transition |
|---|---|---|---|---|---|---|---|---|
| | composition (at. %) | | | | | | layer eff. | layer eff. |
| | | | Er | | | | thickness | thickness |
| Sample | Si | O | (+Yb) | Te | Zn | Na | (nm) | (nm) |
| S1 | 18 | 56.9 | 1.45 | 3.5 | 6.4 | 13.7 | 820 | ~185 |
| S2 | 17 | 60 | 2.8 | 3.6 | 5.8 | 10.8 | 633 | 153 |

The effective doping concentration of Er/Yb in sample S1 and S2 was measured to be 1.45 at.% (0.89×10²¹ cm⁻³) and 2.8 at. % (1.63×10²¹ cm⁻³), respectively. Notably, these are exceptionally high rare-earth doping concentrations in pure silica, without rare-earth clustering. It is observed that the rare-earth content in sample S1 is approximately 50% that of Sample S2. This is related to the individual target ablation times (2 Hrs., each of two targets) in the preparation of S1 which is exactly half of the co-doped target ablation time (4 Hrs. for ne target) for the preparation of S2. The amount of rare-earth ions in S1 can be improved by increasing the processing time that will further help to increase the thickness of RETS layer whereby maintaining the larger spacing between the doped ions.

Optical characterization

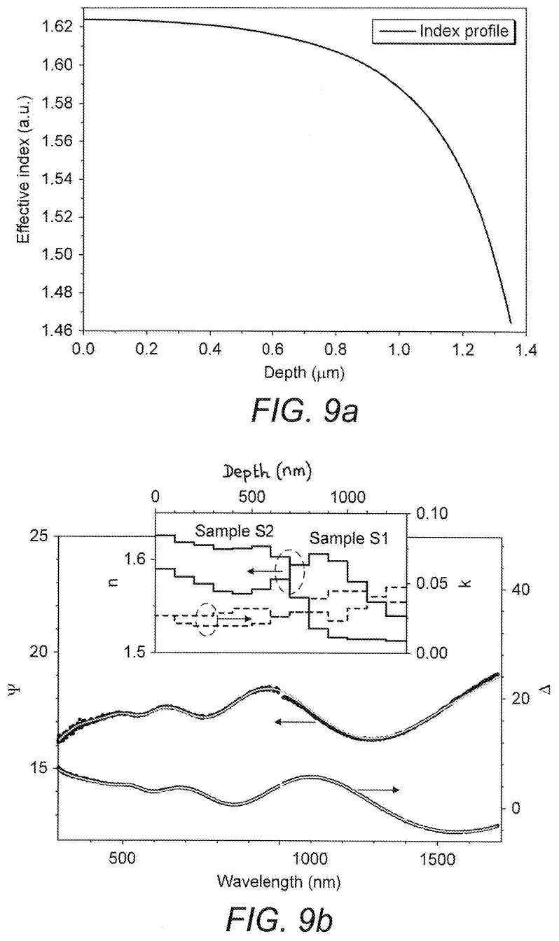

The RETS layers were analyzed for their planar optical layer characteristics using the prism coupler. The layer thickness and refractive indices were obtained at a wavelength of 1550 nm. The planar optical layer thickness for S1 was 1.01 μm, while for S2 it was 0.76 μm with refractive indices of 1.592 and 1.610, respectively. Thus, for a similar overall processing time, a 30% higher thickness is observed with the two-target sequential approach (FIG. 2A) than the single co-doped rare-earth target case (FIG. 2B), while the refractive index of the sole target process is greater. FIG. 9(a) indicates the typical refractive index profile of 1.4 μm RETS layer fabricated through the femtosecond (fs) laser plasma assisted process according to the two-target sequential approach (FIG. 2A). The data reveals the formation of a homogenous layer of step index waveguide with a refractive index of 1.62 on silica at a wavelength of 1550 nm.

The refractive index (n) and extinction coefficient (k) profiles have been further calculated using multi-layer optical models using the ellipsometric data. The optical properties of each sub-layer were calculated using the Cauchy dispersion of n=A+B/λ²+C/λ⁴ (where A denotes the wavelength and A, B and C denote the Cauchy parameters) and the Urbach dispersion of k=De^{Eλ} (where E and D are the Urbach parameters).

The optical properties of the substrates were measured on the polished backside of the samples. The parameters of B and C were fixed at the values of the substrate, whereas parameter E was fixed at the value of the highest absorption surface layer, fitting the UV part of the spectrum with the smallest penetration depth. Consequently, only parameters A and D were fitted, resulting in acceptably low uncertainties. Typical uncertainties of A and D are 10⁻³ and 10⁻¹ in the near surface and bottom interface regions, respectively. FIG. 9(b) shows typical measured and fitted ellipsometric spectra and the depth profiles of the optical properties (in the inset) calculated from the fit. In FIG. 9(b) measured (black dots) and fitted (solid lines) ellipsometric spectra are shown, these measurements were taken at an angle of incidence of 70° for sample S2. The inset shows the depth profiles of the refractive index (n, solid curve) and extinction coefficient (k, dotted line) at the wavelength of 1550 nm for S1 and S2, calculated from the fit.

As seen from the above optical characterization of the RETS layer, sample S1 compared to the sample S2 is higher in thickness and lower in refractive index with similar k values. The drop in thickness and the increased refractive index can be ascribed to the rare-earth ion concentration in the tellurite target glass and hence in the implanted film. The relative concentrations of rare-earth ions is higher as a result of the co-doped single target process (FIG. 2B) as compared to the result of the dual-target sequential ablation process (FIG. 2A).

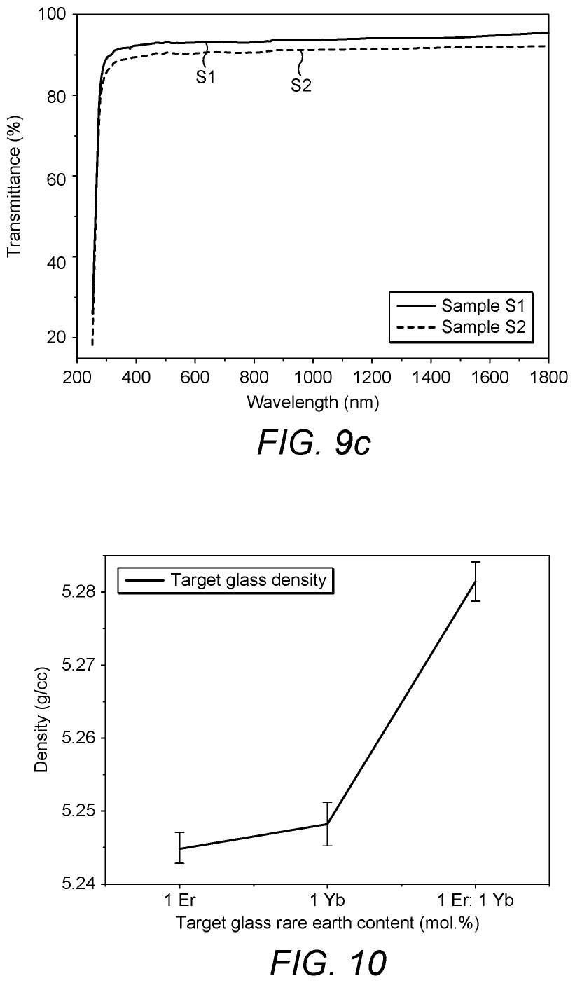

The replacement of Tellurium (Te) with heavier rare-earth atoms gives rise to the density of the target glass, measured using Accupyc 1330 Pycnometer, as indicated in FIG. 10. It can be assumed that the ablation rates for the dense materials are comparatively lower, at a fixed (e.g. fs) laser pulse energy, leading to a drop in the level of ablated materials reaching the surface of the silica substrate. Again, the reduced Te (alkali metal) content in the ablated material may slow down the interfacial reactions with silica and its dissolution, thereby decreasing the rate of formation of the RETS layer and, hence, the RETS layer thickness drops. The addition of rare-earth ions and tellurite ions results in a denser packing of ions in the silica network as shown by the SAED pattern and the refractive index, which is directly linked to the material density. Sample S1 contains a lower rare-earth content (1.45 at. %) as compared to that of S2 (2.8 at. %). The increase of highly polarized trivalent Er³⁺ ions may generate more non-bridging oxygen in the glass network, and the polarizability of the material may thus increase, thereby increasing the refractive index.

The UV-VIS-NIR transmittance of each sample was obtained and is presented in FIG. 9(c). The variations of transmittance with wavelength were comparable for the samples, giving sample S1 the upper value of 95% in the C-band wavelength range. The changes in the transmittance are minimal which can be attributed to the differences in their refractive index and the absorption characteristics of the RETS layer. The optical absorption characteristics are greatly affected with the oxygen bond strength related to the structural changes in the glass system with the addition of Er³⁺ ions. It is obvious that the bond strength depends on the concentration and the oxide state of the glass network modifier ions.

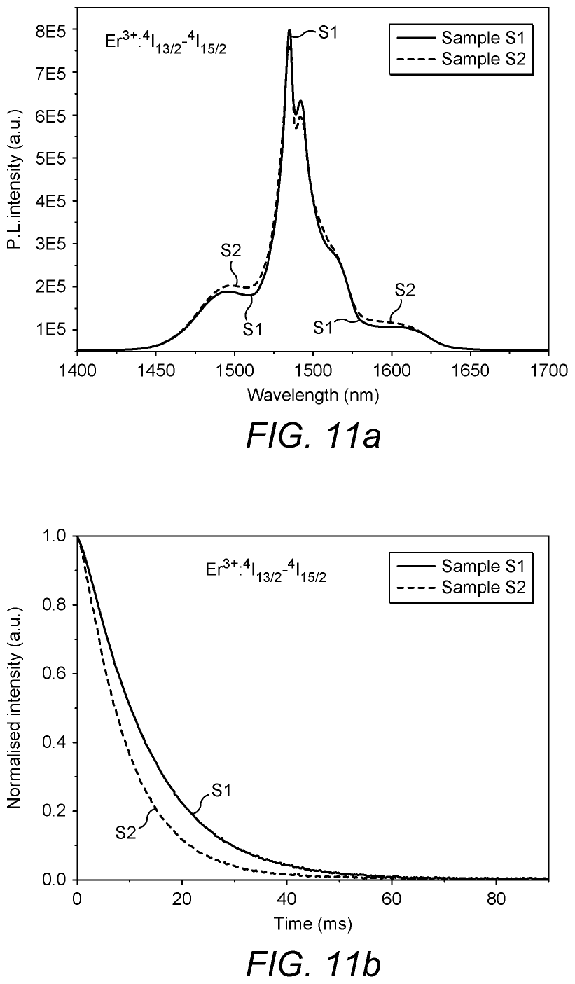

The steady state photoluminescence (PL) emission characteristics were obtained by exciting the glass samples S1 and S2 with a pump source at 30 mW of output power. Under the same experimental conditions, the emission spectral range was scanned from 1400-1700 nm with a resolution of 0.5 nm. The PL spectra for both samples, corresponding to the ⁴I_{13/2}→⁴I_{15/2} transition in Er³⁺ ion, are presented in FIG. 11(a).

The PL emission intensity appears comparable between the two processing strategies, with lower peak intensity for the sample S2. The lifetime of the sample S1 was 12.94 ms, while that of sample S2 was 9.16 ms as shown in FIG. 11(b). The reduced PL intensity and lifetime in sample S2 are likely to be due to the relatively higher concentration of Er³⁺ ions, leading to concentration quenching of the ⁴I_{13/2}→⁴I_{15/2} transition. It is postulated that the increased concentrations of rare-earth ions decrease the ion spacing to an extent where dipole-dipole interactions between the Er³⁺ ions are prominent and energy migration occurs. Furthermore the higher erbium concentration may create a relatively larger polar environment, validated by the higher refractive index of the sample S2. The fluorescence lifetime may tend to be shorter in the more polar environment as the system possibly tries to stabilize as quickly as possible from the excited level by radiative emissions.

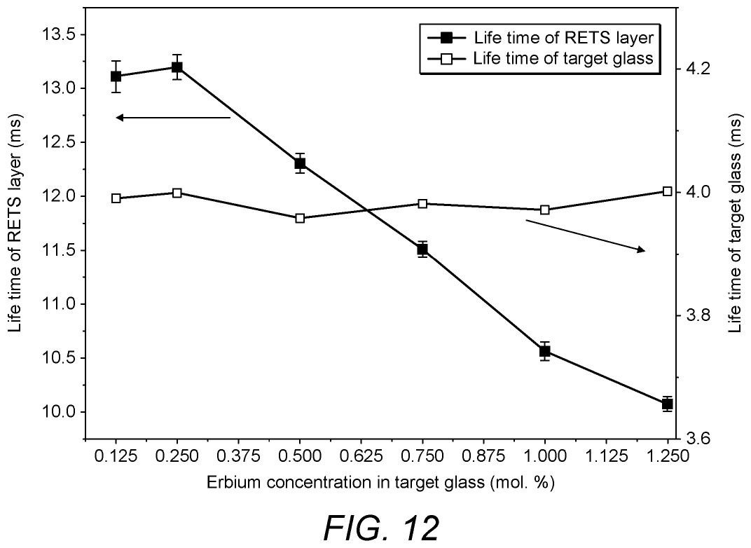

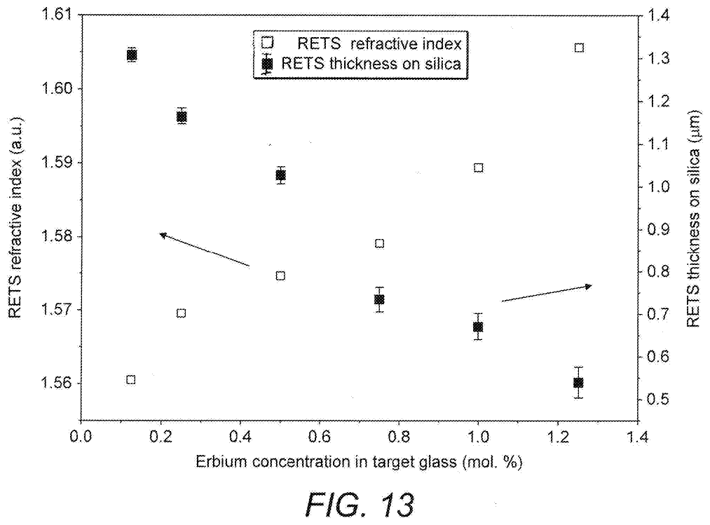

The variation of PL lifetime with respect to the Er³⁺ ions concentration in the Er-doped target glass is shown in FIG. 12. This shows the measured PL lifetime of the ⁴I_{13/2}-⁴I_{15/2} transition of Er³⁺ ions within the RETS (left-hand axis of graph) produced according to the sequential ablation method (FIG. 2A) in which one of the target glasses is an erbium-doped tellurite target glass (the other being a Yb-doped target glass). The PL lifetime of that target glass is also shown (right-hand axis of graph) as a function of Er³⁺ ion concentration in that target glass. The lifetime for the RETS layer reduces with increasing Er³⁺ ions concentration within the Er-doped target glass. According to FIG. 11, a 0.125 mol.% Er³⁺ concentration in the Er-doped target glass results in a PL lifetime in the ion-implanted substrate of 13.2 ms while concentration in the Er-doped target glass of 1.25 mol. % results in a PL lifetime in the ion-implanted substrate of around 10ms. It is postulated that the marginal lifetime decrease is due to the increase in the concentration of Er³⁺ ions which reduces the average spacing between the erbium-erbium ions. Consequently, it is postulated that the electric-dipole interactions become more pronounced, facilitating energy transfer between Er³⁺ ions which contributes to the reduction in fluorescence lifetime. It is also observed, as shown in FIG. 13, that the effective thickness (right-hand axis of graph) of the ion-implanted RETS layer decreases with increasing Er³⁺ ion concentration in the Er-doped target glass, whereas its refractive index (left-hand axis of graph) increases, with increasing Er³⁺ ion concentration in the Er-doped target glass.

In this way, the PL lifetime, refractive index and layer ion-implanted layer thickness may each be controlled as desired according to the appropriate choice of Er³⁺ ion concentration in the Er-doped target glass used in the according to the sequential ablation method (FIG. 2A) in which one of the target glasses is an erbium-doped tellurite target glass (the other being a differently-doped, e.g.Yb-doped, target glass).

### Discussion

In summary, in a preferred and illustrative embodiment of the present invention, it has been shown that high doping levels of rare-earth ions (Yb³⁺ sensitized Er³⁺ ions) are achieved in silica without crystallization. This was achieved using laser-induced plasma assisted hybrid integration of ions from two separate/different rare-earth ion enriched tellurite target glasses into a silica substrate. The highly energetic ions in the laser-induced plasma enabled the formation of a metastable RETS layer. It is postulated that an appropriate substrate temperature further supports or enhances this process. The higher oxygen content in the RETS network promotes stable oxide formation, which is desirable for improved fluorescence efficiency. Substantial rare-earth ion doping concentrations of 0.89×10²¹ atoms/cm³, and a very high PL lifetime-density product of 1.49×10¹⁹ s.cm⁻³.

The distinctive interlayer mixing accomplished the effective sensitization of rare-earth ions (e.g. sensitization of Er³⁺ with Yb³⁺ ions). This is in spite of expectation to the contrary due to the sequential nature of the target ablation used to generate these ions from two different and separate ablation targets. Indeed, the two-target sequential approach enhanced the RETS layer characteristics still further. In particular, lower rare-earth concentrations of the target glass enabled a thicker RETS layer formation on silica for a given processing time. This enables production of a homogeneous distribution of doped ions in a substrate, with larger average spacing thereby permitting higher doping concentration without significant fluorescence quenching. The methodology also surpasses the comparative co-doped single target ablation approach with a 35% longer PL lifetime which is highly beneficial for EDSWs. The method provides substantially homogeneously doped step index planar optical layers with high index contrast and enhanced thicknesses on a substrate platform that strongly supports the development of loss compensated photonic integrated circuits.

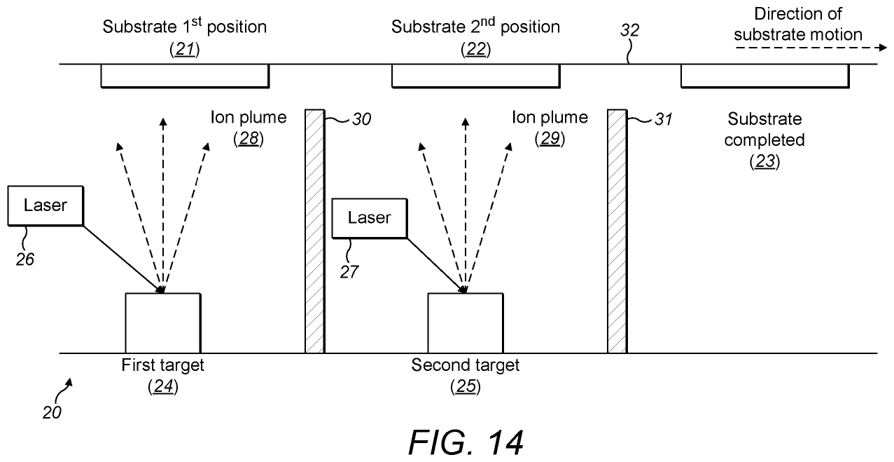

It is to be understood that the method of producing the implanted substrate, in other embodiments of the invention, is not limited to the sequential ablation process illustrated in FIG. 2A, and may be implemented by a process of simultaneous ablation of two different target materials. An example is shown schematically FIG. 14 in which the ablating of material from a second target 25 is performed substantially simultaneously with the ablating of material from a first target 24. The method includes, in this example, sequentially: obstructing firstly the plume of ions 29 from the second target 25 to the substrate in a first position 21 adjacent the first target 24, and subsequently obstructing the plume of ions 28 from the first target 24 when the substrate is moved to a second position 22 adjacent the second target 25. Thus, sequentially, the plume of ions 28 from the first target 24 reaches the substrate 21 before subsequently the plume of ions 29 from the second target 25 reaches the substrate. The obstruction takes the form of a static barrier 30 (31) partitioning and separating the first target material 24 from the second target material 25.

The static barrier 30, in effect, periodically is caused to block the path of an ion plume moving towards the substrate from the second target material and then from the first target material. It intercepts one ion plume or the other as the substrate itself is moved to be positioned 21 above the first material (but not the second one) and then positioned 22 above the second target material (but not the first one). At each of these positions of the substrate, one of the two target materials is behind an obstruction (e.g. the static barrier) while the other is not. Finally, after implantation of ions from the second target is completed, the substrate may be conveyed from its second position 22 to a subsequent position 23 for further processing or completion. In this way, control of the sequence of arrival of ion plumes from the two different targets is able to be achieved and controlled. In particular, this example may be implemented as a conveyor 32 arrangement carrying multiple substrates, spaced-apart so that the conveyer may intermittently stop to place any one substrate above one of the two target materials, with the other target material being obstructed by the barrier.

The conveyor 32 may then move substrate forward to a position over the next target material. The two target materials are continuously ablated during the whole period such that each substrate receives a plume of ablated ions separately and in sequence. The process may be conducted in one vacuum chamber where the temperature can be more easily controlled. The conveyor may carry many substrates which are conveyed, one after the other to positions over the first target material, then the second target material, so as to receive ion plumes from them sequentially. All the while, both target materials may be undergoing laser ablation continuously and simultaneously.

In further embodiments, the ablating of material from the second target is performed after the ablating of material from the first target material, the method including sequentially obstructing first the quantity of ions from the first target material and subsequently obstructing the quantity of ions from the second target material so that sequentially the quantity of ions from the first target material reaches the substrate before the subsequent quantity of ions from the second target material. In yet further embodiments, the ablating of material from the second target material is performed substantially after the ablating of material from the first target material, the method including positioning the substrate closer to the first target material than the second target material so that sequentially the quantity of ions from the first target material reaches the substrate before the subsequent quantity of ions from the second target material. Consequently, the sequenced arrival, at the substrate, of separate, of successive plumes of target materials, may be enabled either with simultaneous ablation of the targets or with successive ablation of targets.

The embodiments and examples of the invention descried above and provided to aid an understanding of the invention and are not intended to limit the scope of the invention, such as may be defined by the claims. It is to be understood that variants, modifications and equivalents of any one or more element of an embodiment, such as would be readily apparent to the skilled person, is within the scope of the invention such as may be defined by the claims.

1. A process for fabricating a substrate comprising an ion-implanted layer, the process comprising:
ablating ions from a first target with incident radiation from a laser in the presence of a substrate whereby a quantity of ablated ions from the first target is implanted into the substrate;
ablating ions from a second target with incident radiation from a laser in the presence of said substrate whereby a quantity of ablated ions from the second target is implanted into the substrate and amongst said implanted ions from the first target;
wherein ablated ions of the first target are a different material not comprised amongst ablated ions of the second target.

2. A process according to claim 1 wherein said ablating of material from said second target is performed after said ablating of material from said first target.

3. (canceled)

4. (canceled)

5. A process according to claim 1 in which said ablating material from said first and second targets is repeated sequentially a plurality of times.

6. (canceled)

7. (canceled)

8. (canceled)

9. A process according to claim 1 in which said substrate is heated.

10. A process according to claim 9 in which said substrate is heated to a temperature less than the glass softening point/temperature, or not exceeding the temperature of crystallization, of the material of the substrate.

11. (canceled)

12. (canceled)

13. (canceled)

14. (canceled)

15. (canceled)

16. (canceled)

17. (canceled)

18. A process according to claim 1 wherein at least one of the first target and the second target comprises a glass comprising ions of a transition metal and said ablated material from the at least one of the first target and the second target comprises Lanthanide ions.

19. (canceled)

20. A process according to any of claim 18 in which a said ions of a transition metal is an ion from amongst the following: erbium, ytterbium, neodymium, praseodymium, holmium, cerium, yttrium, samarium, europium, gadolinium, terbium, dysprosium or lutetium, holmium.

21. A process according to claim 1 wherein at least one of the first target and the second target comprises a glass from amongst the following: tellurium-based glass, e-r-a chalcogenide-based glass, a germanium-based glass, a bismuth-based glass, a silicon-based glass, a phosphate glass.

22. (canceled)

23. A process according to claim 1 wherein the laser is a Femtosecond laser and the process includes ablating at least one of said first andiar said second target with said incident radiation comprising femtosecond laser pulses of peak intensity not less than the threshold laser ablation intensity of the target material.

24. (canceled)

25. A process according claim 1 wherein the substrate is a glass selected from: silica, silicate, phosphate, tellurite, tellurite derivatives, germanate, bismuthate and solgel route glasses, or an optical polymer.

26. A process according claim 1 wherein the substrate is a selected from: silicon, a composite substrate comprising a silica layer formed upon a silicon layer, a composite substrate comprising a silicon layer formed upon a layer of an insulator material.

27. A process according to claim 26 wherein the optical polymer is selected from: Poly(methyl methacrylate), polyvinyl alcohol, polyether ether ketone, polyethylene terephthalate, polyimide, polypropylene, polydimethylsiloxane (PDMS) and polytetrafluoroethylene.

28. A process according to claim 1 wherein said ion-implanted layer has a substantially uniform distribution of the implanted ions substantially from the surface of the substrate.

29. A process according to claim 1 wherein said ion-implanted layer has an implanted ion density of at least about 10¹⁵ ions cm⁻³.

30. (canceled)

31. (canceled)

32. A substrate comprising an ion-implanted layer containing implanted ions which are at least one of: transition metal ions andier Lanthanide ions, mixed with different implanted ions which are at least one of: transition metal ions andief Lanthanide ions, wherein the implanted ion density is at least about 10¹⁵ ions cm⁻³.

33. A substrate comprising a photo-luminescent ion-implanted layer containing implanted ions which are at least one of: transition metal ions and Lanthanide ions, mixed with different implanted ions which are at least one of: transition metal ions and/or Lanthanide ions, wherein the photo-luminescent ion-implanted layer has a photo-luminescence lifetime-density product of at least about 9×10¹² seconds/cm³.

34. A substrate comprising a photo-luminescent ion-implanted layer containing implanted ions which are at least one of: transition metal ions and/or Lanthanide ions mixed with different implanted ions which are at least one of: transition metal ions and/or Lanthanide ions wherein the penetration depth of the implanted ions is at least one atomic layer.

35. A substrate according to any one of claims 32 to 34 wherein the extent of the ion implanted layer has a substantially uniform distribution of the implanted ions substantially from the surface of the substrate.

36. (canceled)

37. (canceled)

38. (canceled)

39. (canceled)

40. (canceled)

41. (canceled)

42. A waveguide comprising a substrate according to any one of claims 32 to 34.

43. An optical component comprising a substrate according to any one of claims 32 to 34 claim and providing an optical gain per unit length exceeding 5dB/cm.
